(19) United States
(12) Patent Application Publication
(10) Pub. No.: US 2013/0170112 A1
(43) Pub. Date: Jul. 4, 2013

(54) ELECTRONIC DEVICE

(71) Applicants: PING LI, Shenzhen City (CN); XUE-FENG WAN, Shenzhen City (CN); YUAN-MING WANG, Shenzhen City (CN); BAO-GANG ZHAO, Shenzhen City (CN)

(72) Inventors: PING LI, Shenzhen City (CN); XUE-FENG WAN, Shenzhen City (CN); YUAN-MING WANG, Shenzhen City (CN); BAO-GANG ZHAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/559,225

(22) Filed: Jul. 26, 2012

(30) Foreign Application Priority Data
Dec. 28, 2011 (CN) 201110446821.4

(51) Int. Cl. H05K 5/00

(52) U.S. Cl. 361/679.01

(57) ABSTRACT

An electronic device includes a panel, and a first housing, to maintain an aesthetic quality to the electronic device when assembled. The panel has a main body, and a first sidewall extending from the main body. The first housing has a top board, and a second sidewall extending from the top board. The second sidewall has a blocking member. The second sidewall is located outside of the first sidewall, and the blocking member is located inside of the first sidewall to stop the second sidewall moving with respect to the first sidewall.

### BACKGROUND

1. Technical Field

The present disclosure relates to electronic devices, and particularly to a fastening structure for fastening a panel of an electronic device.

2. Description of Related Art

Electronic devices, such as DVD players, MP3 players, and set top boxes (STBs), include a top cover, a bottom cover, and a panel coupled between the top cover and the bottom cover. The top cover and the bottom cover are both made of metal sheet, and fastened together by screws, thus, the top cover and the bottom cover may be easily deformed to allow a gap between top cover and the panel or the seam between the bottom cover and the panel to be misaligned, Which ruins the aesthetic of the electronic device.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded view of an electronic device having a first housing and a panel.

FIG. 2 shows the first housing and the panel in FIG. 1, but viewed from a different aspect.

FIG. 3 is an enlarged view of the circled portion III in the FIG. 2.

FIG. 4 shows a state of the panel being assembled to the first housing.

FIG. 5 is an enlarged view of the circled portion V in the FIG. 4.

FIG. 6 is a cutaway view of the electronic device in FIG. 1.

FIG. 7 is an enlarged view of the circled portion VII in FIG. 6.

### DETAILED DESCRIPTION

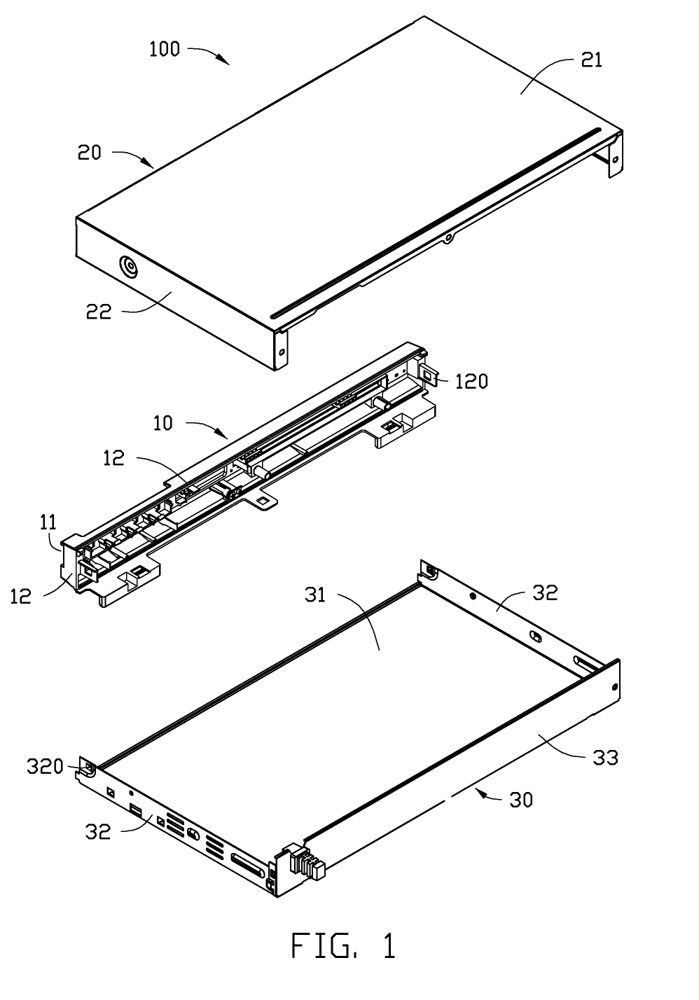

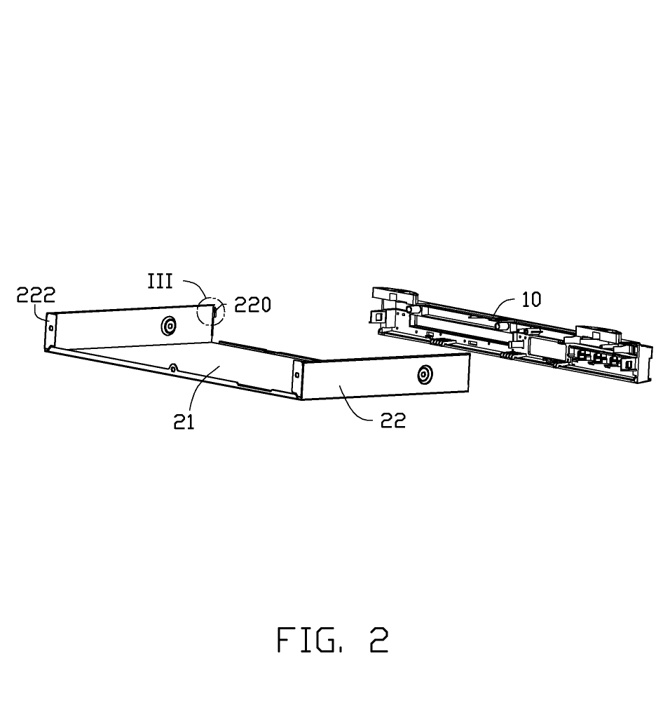

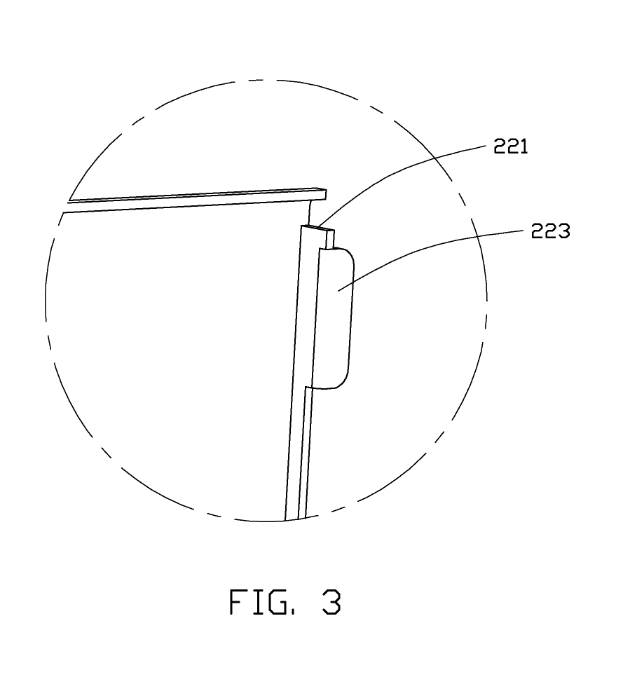

Referring to FIGS. 1-3, an electronic device 100 includes a panel 10, a first housing 20, and a second housing 30. The panel 10 is made of plastic. The first housing 20 and the second housing 30 are made of metal sheeting.

The panel 10 includes a rectangular main body 11, and four first sidewalls 12 extending from the four edges of the main body 11. The four first sidewalls 12 are connected end-to-end. The panel 10 further includes two first grasping members 120 extending from the ends of the main body 11. The first grasping members 120 are adjacent to two of the first sidewalls 12. The first grasping members 120 protrude out of the sidewalls 12. In this embodiment, each first grasping member 120 defines a hole.

The first housing 20 includes a rectangular top board 21, and two second sidewalls 22 perpendicularly extending from the two ends of the top board 21. A blocking member 220 and a fastening member 222 respectively protrude from the two ends of each second sidewall 22. The fastening member 222 is a rectangular board perpendicularly extending from the second sidewalls 22. The blocking member 220 includes a rib 221 perpendicularly protruding from the second sidewall 22, and an arm 223 connected to the rib 221. The ribs 221 and the fastening members 222 extend in the same direction, the ribs 221 face each other, the fastening members 222 also face each other. Each arm 223 is a strip board which is connected to one rib 221. The arm 223 is parallel to the second sidewalls 22.

The second housing 30 includes a rectangular bottom board 31, two third sidewalls 32 perpendicularly protruding from opposite edges of the bottom board 31, and a fourth sidewall 33 perpendicularly protruding from another edge of the bottom board 31 and connected between the third sidewalls 32. Two second grasping members 320 protrude from the third sidewall 32, to be fastened to first grasping member 120 In this embodiment, the second grasping member 320 includes a tab.

The assembling of the panel 10, the first housing 20, and the second housing 30 are described below.

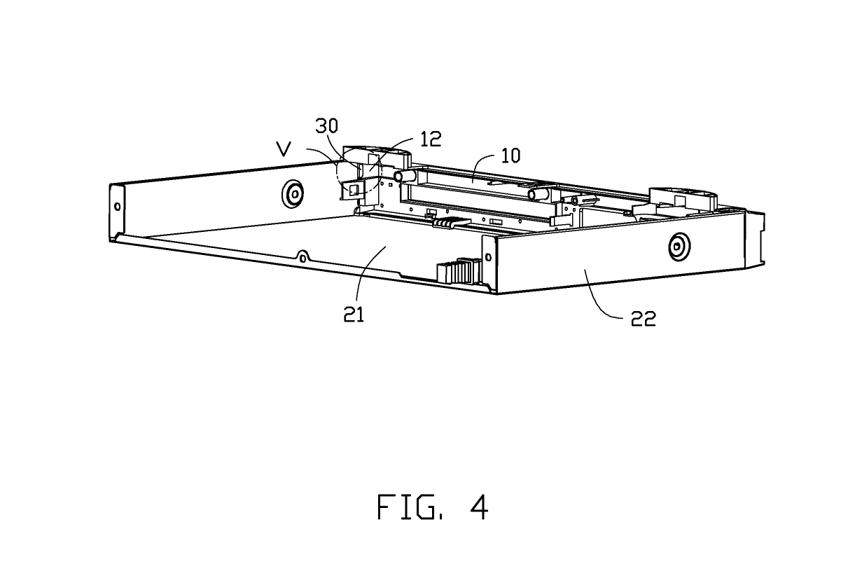

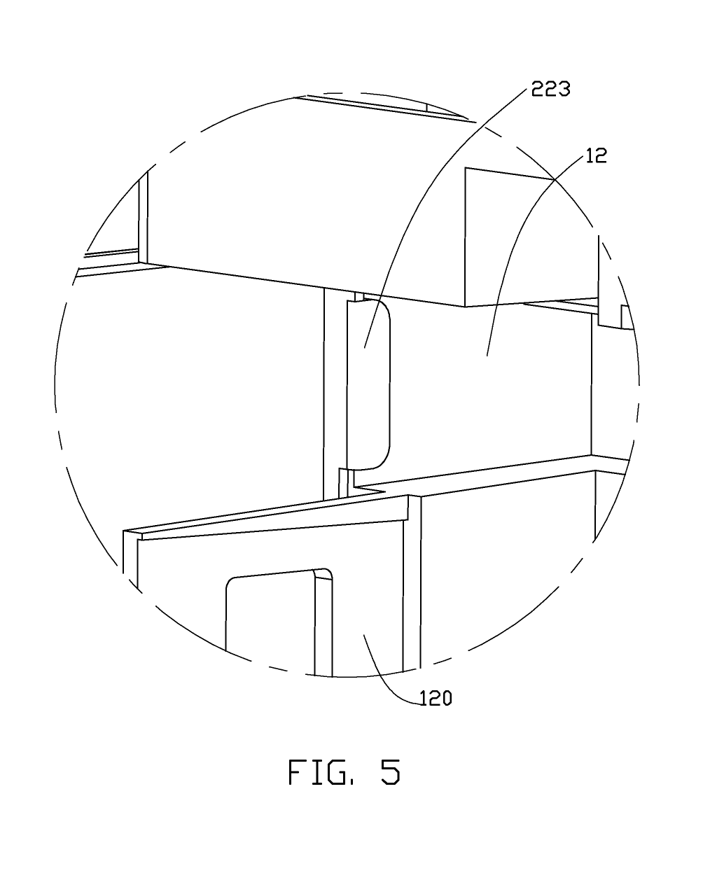

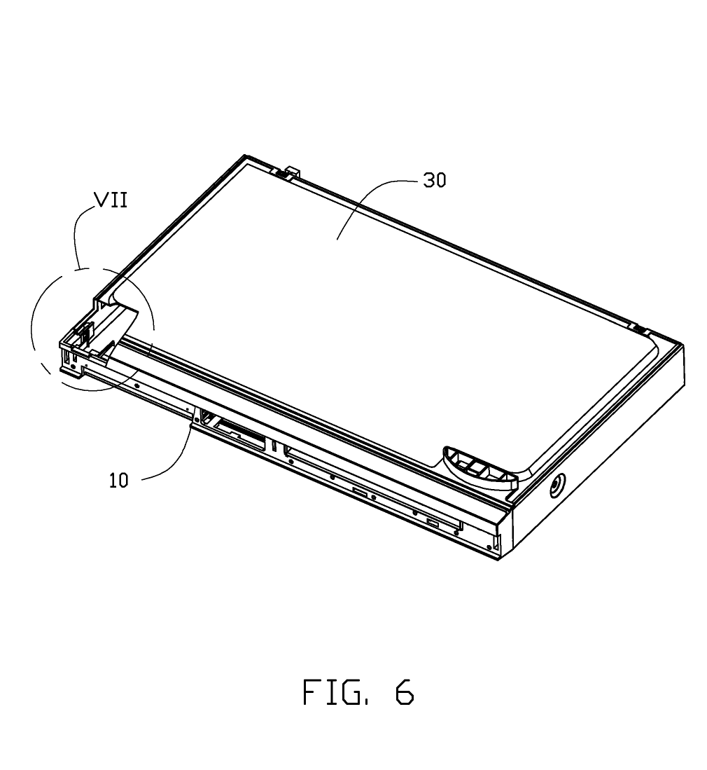

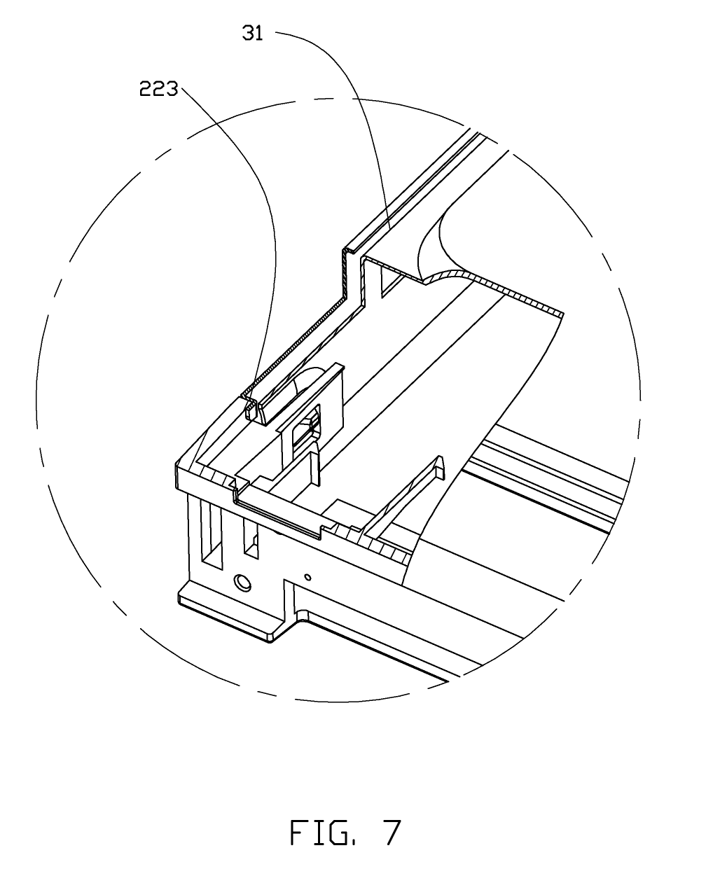

Referring to FIGS. 4-7, first, the first grasping members 120 are fastened to the second grasping members 320 that the panel 10 is fastened to the second housing 30; the main body 11 faces the fourth sidewall 33; the first sidewalls 12 to which the first grasping members 120 are adjacent are located between the second sidewalls 22. Second, the first housing 20 is placed on the second housing 30 and panel 10 such that the top board 21 faces the bottom board 31; the top board 21 covers one first sidewall 12 away from the bottom board 31; the third sidewalls 32 is located between the second sidewalls 22; the arms 223 are located inside the first sidewall 12 to which first grasping member 120 is adjacent, and the arms 223 are blocked by the first sidewalls 12; the arms 223 are located between the first grasping member 120 and the bottom board 31, and the arms 223 are blocked by the bottom board 31; the fastening members 222 are located outside of the fourth sidewalls 33 and located on the two ends of the fourth sidewall 33. Third, the first housing 10 is fastened to the second housing 30 by screws (not shown), for example, two first sidewalls 12 and the third sidewall 32 is fastened by screws; the fastening member 222 and the fourth sidewall 33 is also fastened by the screws.

As describe above, the first housing 20 is fastened to the second housing 30 by screws such that a force will be applied to the second sidewalls 22 to splay the second sidewalls 22, but because the arms 223 are blocked by the first sidewalls 12, the second sidewalls 22 cannot splay. Further, the first housing 20 is fastened to the second housing 30 by screws such that a force will be applied to the second sidewalls 22 to distort the joint between the second sidewalls 22 and the top board 21 such that the second side walls 22 will be moved to the bottom board 31, but because the arm 223 is blocked by the bottom board 31, the second sidewalls 22 is stopped from moving to the bottom board 31. In another embodiment, there is a gap (not shown) between the arms 223 and the bottom board 31 which is smaller than 0.5 mm, and which allows for distortion of the first housing 20, but the aesthetic of the electronic device 100 is entirely unaffected.

Even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
a panel having a main body, and a first sidewall extending from the main body; and
a first housing having a top board, and a second sidewall extending from the top board, the second sidewall having a blocking member;
wherein the second sidewall is located outside of the first sidewall, and the blocking member is located inside of the first sidewall to stop the second sidewall moving with respect to the first sidewall.

2. The electronic device of claim 1, wherein the blocking member comprises a rib perpendicularly extending from the second sidewall, and an arm connected to the rib, the arm is parallel to the second sidewall.

3. The electronic device of claim 1, further comprising a second housing fastened to the first housing, the second housing comprising a bottom board facing the top board, the main body is located between the top board and the bottom board, the arm is supported by the bottom board.

4. The electronic device of claim 3, wherein the second housing is made of metal sheets.

5. The electronic device of claim 1, further comprising a second housing fastening to the first housing, the second housing comprising a bottom board facing the top board, the main body is located between the top board and the bottom board, there is a gap between the arm and the bottom board, the gap is smaller than or equal to 0.5 mm.

6. The electronic device of claim 5, wherein the second housing is made of metal sheets.

7. The electronic device of claim 1, wherein the first housing is made of metal sheets.

8. The electronic device of claim 1, wherein the panel is made of plastic.
